(19) United States
(12) Patent Application Publication
(10) Pub. No.: US 2012/0256205 A1
(43) Pub. Date: Oct. 11, 2012

(54) LED LIGHTING MODULE WITH UNIFORM LIGHT OUTPUT

(76) Inventors: Tek Beng Low, Melaka (MY); Eng Wah Tan, Melaka (MY)

(21) Appl. No.: 13/440,512

(22) Filed: Apr. 5, 2012

(30) Foreign Application Priority Data
Apr. 6, 2011 (MY) PI 2011001539

(51) Int. Cl. H01L 33/52

(52) U.S. Cl. 257/88; 257/E33.059

(57) ABSTRACT

The invention relates to a light emitting diode (LED) module that is characterized by a thermally conductive substrate which is used as the base of the module; and a plurality of cavities positioned on the module; and a plurality of LED semiconductors chips are mounted within each cavity. Within each cavity; secondary cavities are formed and a plurality of LED semiconductors chips are mounted within each of the secondary cavity. A multiple layer configuration of encapsulation is used to fill the cavities to help mix and diffuse the light from the LED chips and ensure that we achieve a uniform light output from the light emitting surface of the module.

### FIELD OF INVENTION

The invention relates to a light emitting diode (LED) module that can be used for general lighting applications, display back-lighting and signage. The module is characterized by a thermally conductive substrate which is used as the base of the module; and a plurality of cavities positioned on the module; and a plurality of LED semiconductors chips are mounted within each cavity. Within each cavity; secondary cavities are formed and a plurality of LED semiconductors chips are mounted within each of the secondary cavity.

### PRIOR ART

Optoelectronic components such as LED are widely used in the world today especially for lighting and signaling applications. Conventionally, LED semiconductors chips are first packaged within a housing to form a component. The housing typically consists of a metal lead-frame which is used as the base to attach the chip. Electrically conducting wires are then bonded to connect the chip to the lead-frame terminals. A transparent or diffused encapsulant is then molded onto the assembly to form the complete housing. This housing provide the necessary protection for the semiconductor chip from the environment and enable the part to be subsequently soldered onto printed circuits boards using conventional surface mounting technology. FIG. 1 show how a typical LED light bar can be constructed using LED components which were mounted and soldered onto a printed circuit board (PCB).

Alternatively, there is another approach where a component is not used. LED semiconductor chips are directly attached onto a PCB. Electrically conductive wires are used to connect the chips onto the circuit printed on the PCB. Encapsulant material with high viscosity is then potted onto the chips and wires as a means to protect the assembly. This approach is commonly known as the chip on board technique (COB).

An example of such COB technique is as described WO 02/05351. The prior art described the method where several LEDs without housings are mounted onto a printed circuit board and the LEDs are potted using a highly transparent polymer. A reflector is then placed on the printed circuit board from above around each LED. The diameter of the potting compound is at least equal to the internal diameter of the reflectors in such a way that the reflectors lies in direct contact with the printed circuit board and the surface of the potting compound is configured as an optically active lens surface.

However, this method has its disadvantages. It is typically costly and difficult to produce a potting which can be configured as an optically active lens surface. The profile of the potting may vary from lens to lens and this will affect the optical characteristics. In addition, an optimum reflector design is critical in such design in order to match with the potted lens and ensure that light is efficiently extracted from the LEDs and projected to the required direction.

In addition, the optical characteristics of such COB technique and the conventional light bar resembles a series of point light source. The light intensity along the direction of the board is not uniform. In addition, the optical content of each of the light source may also be different from each other and there is no optical mixing between the individual light sources to generate a more uniform light output. This differs greatly from conventional light sources such as the linear cold cathode fluorescent lamp (CCFL) where the light output is very consistent and uniform across the emitting surface.

This patent will try to describe an alternative method that will simplify the construction of the lighting module and also provide a uniform light output across the light emitting surface.

### DESCRIPTION OF DRAWINGS

The drawings enclosed are as follows:

FIG. 1 illustrates a typical LED light bar constructed using LED components which were mounted and soldered onto a printed circuit board (PCB);

FIG. 2 illustrates the first embodiment of the present invention;

FIG. 3 illustrates an enlarged view of the first embodiment of the present invention;

FIG. 4 illustrates the rear view of the first embodiment of the present invention;

FIG. 5 illustrates the cross section view of the first embodiment of the present invention;

FIG. 6 illustrates the second embodiment of the present invention;

FIG. 7 illustrates the cross section view of the second embodiment of the present invention.

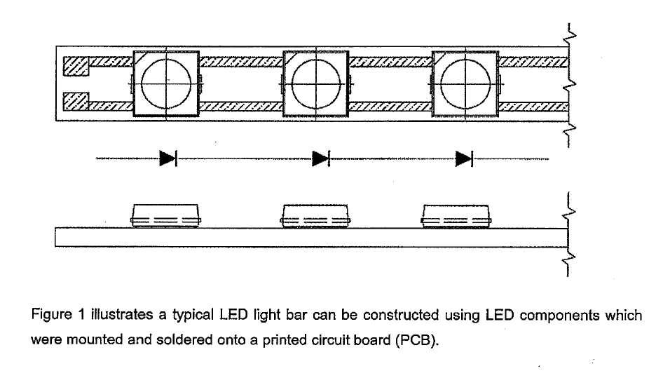

### DETAIL DESCRIPTION

In accordance to the present invention, a thermally conductive substrate is used as the base of the module. Typical materials that can be used include metals such as aluminum, copper and other forms of copper alloy. Besides that, non-metals such as ceramic, AIN and hybrid fibre glass reinforced substrate with enhanced thermal via or thermal plug can also be used as the substrate. The key property required is high thermal conductivity between the surface where the LED chips are located and the surface where heat is dissipated to the environment. This thermally conductive substrate will serve as the heat-sink for the module besides providing the base for the module. When this substrate surface is mounted onto a larger secondary surface, heat can be more effectively dissipated away to the external environment.

On the top surface of the thermally conductive substrate, an electrical isolated material is laminated or attached onto a portion or the whole surface of the substrate. This electrically isolated material will provide the plane for electrical traces and pads to be constructed; and provide the electrical connections between the LED chips and external connecting interface. The electrically isolated material will also ensure that the electrical traces will be electrically isolated from the thermally conductive substrate below. By ensuring that the thermally conductive substrate is always electrically isolated, this design easily allows the thermally conductive substrate to be mounted onto a secondary surface for the next level of heat dissipation without the risk of electrical contact.

Multiple cavities are formed on the substrate. These cavities are typically molded or injection molded onto the substrate. Suitable materials to form the housing included engineering plastics such as PPA, LCP and high temperature nylon. In addition, thermoset resin and silicone material can also be used to mold the cavities. Besides molding the cavities; other techniques such as lamination or stencil printing can also be used to create the cavities. In order to ensure that these cavities are strongly attached onto the thermally conductive substrate; half-etch holes or cut-outs are made on the rear side of the substrate so that molding material can fill into these areas during molding and subsequently become an entity that will lock and grip the cavities onto the substrate. These locks are located on every cavity and do not protrude beyond the rear plane of the thermally conductive substrate. This is important to ensure that no protrusion is allowed on this rear plane that may hamper subsequent mounting to a secondary surface.

Each of these cavities are spaced at regular intervals and the gap between two adjacent cavities are limited to less than 5 mm to ensure that we have a uniform light distribution across the entire module. If the gap is larger, dark spot will be observable in these gaps.

These cavities are used a means to contain the encapsulation material that will be filled into the cavities and provide a seal and protection for the chips from the environment. In addition, the material used for the cavity is typically white in color and the cavity internal walls are smooth in order to serve as a reflector to improve light extraction for the module. The internal wall can be also fine polished and inclined at an angle to further improve its reflectivity. Metallic coating can also be applied to the walls to achieve close to mirror finish and will further boost the reflectivity. The optical effect due to the internal reflector wall is highly repeatable as the dimension and contour of the walls are very consistent due to the material property and molding process.

Secondary cavities are formed within each of the main cavity. LED chips will be mounted within the secondary cavities. The chips can be mounted using epoxy glue, silicone glue or other adhesive material. For even more superior thermal connection, eutectic chip attach or metallic solder can also be used. This construction will ensure superior thermal conductivity as the LED chips are now directly attached to a thermally conductive substrate.

A minimum of two different encapsulant materials will be used to fill the cavities. The secondary cavity is first filled with clear encapsulant material or clear encapsulant material mixed with luminescence conversion elements such as phosphor. After the secondary cavities are filled and cured; a second clear or diffused encapsulant is used to fully fill the whole cavity. This two layer configuration of encapsulation material is intended to help mix and diffuse the light from the LED chips and ensure that we achieve a uniform light output from the light emitting surface of the module. This two layer configuration can also be enhanced into multiple layers with each layer having different optical properties to achieve the desired effects.

Typical encapsulant systems used are epoxy resin and silicone. The encapsulant material is easily dispensed into the cavities and subsequently cured under temperature. Luminescence conversion elements such as phosphor may also be added into this encapsulant if certain optical conversion is required. Commonly used luminescence conversion elements include yttrium aluminum garnets (YAG), silicates and nitrides. Other materials such as silica used as diffusant may also be added in order to improve the optical characteristics of the conversion.

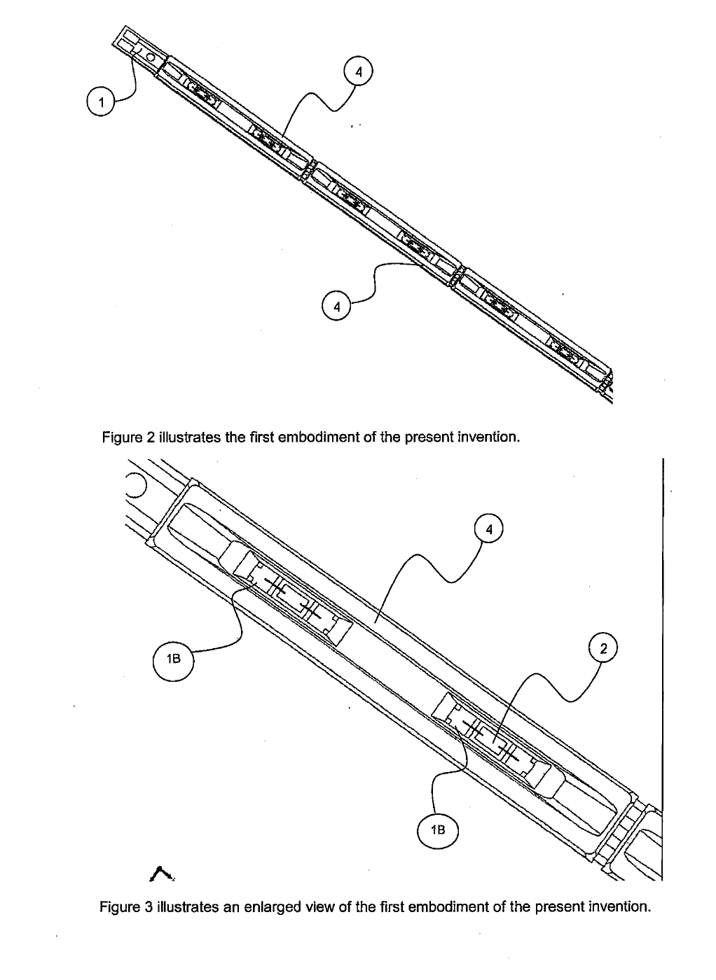

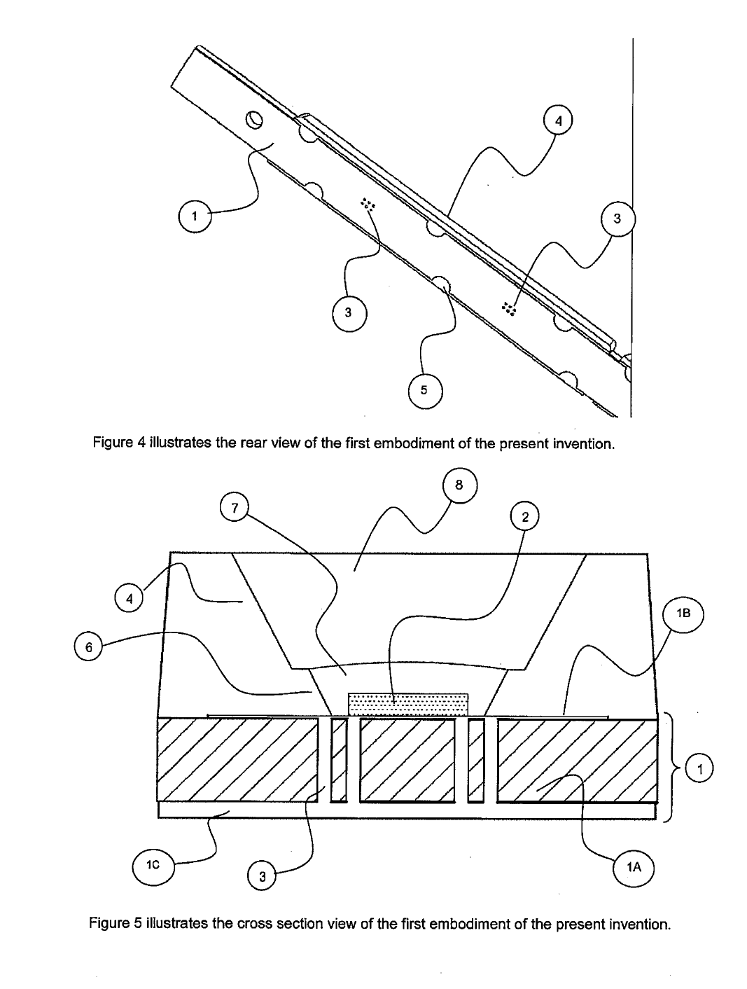

In the first embodiment of the present invention, FIGS. 2, 3, 4, and 5 illustrates a linear lighting module. A thermally conductive substrate (1) is used as the base of the module. The core of the substrate (1A) is an electrically non-conductive material. Suitable material include fibreglass reinforced epoxy and ceramic. On the bottom of this layer is a thermally conductive material (1C) such as copper and aluminum. Both of these layers are laminated or attached together to form the substrate (1). The electrically non-conductive material (1A) will provide the plane for electrical tracks (1B) and pads (1B) to be constructed. LED chips (2) will be attached to the pads and the electrical tracks will provide the electrical connections between the LED chips (2) and external connecting interface. The top pads where the chips are attached are connected to the bottom layer (1C) via thermally conductive holes or plug-throughs (3). These connections ensure good thermal connection between the top and bottom layers and at the same time electrical isolation between the layers. The thermal connection is provided typically via plated through holes or plugging the holes using conductive material such as copper. Multiple cavities (4) are formed on the substrate. The cavities are spaced linearly with a gap in between two adjacent cavities of less than 5 mm. These cavities are typically molded or injection molded onto the substrate. Suitable materials to form the housing included engineering plastics such as PPA, LCP and high temperature nylon. Other materials such as white silicone can also be used. In order to ensure that these cavities are strongly attached onto the thermally conductive substrate (1); half-etched holes or cut-outs (5) are made on the rear side of the substrate so that molding material can fill into these areas during molding and subsequently become an entity that will lock and grip the cavities onto the substrate. LED chips (2) are mounted within the cavities. The cavity (4) is designed in such a way whereby a secondary cavity (6) is formed within the main cavity (4). The secondary cavity (6) is first filled with clear encapsulant material or clear encapsulant material mixed with luminescence conversion elements such as phosphor (7). After the secondary cavities are filled and cured; a second clear or diffused encapsulant (8) is used to fully fill the whole cavity. This two layer configuration of encapsulation material is intended to help mix and diffuse the light from the LED chips and ensure that we achieve a uniform light output from the light emitting surface of the module. Typical material used as encapsulant includes epoxy resin systems or silicone. Luminescence conversion elements such as phosphor are added if certain optical light conversion is required.

Commonly used luminescence conversion elements include yttrium aluminum garnets (YAG), silicates and nitrides. Other materials such as silica used as diffusant may also be added in order to improve the optical characteristics of the conversion.

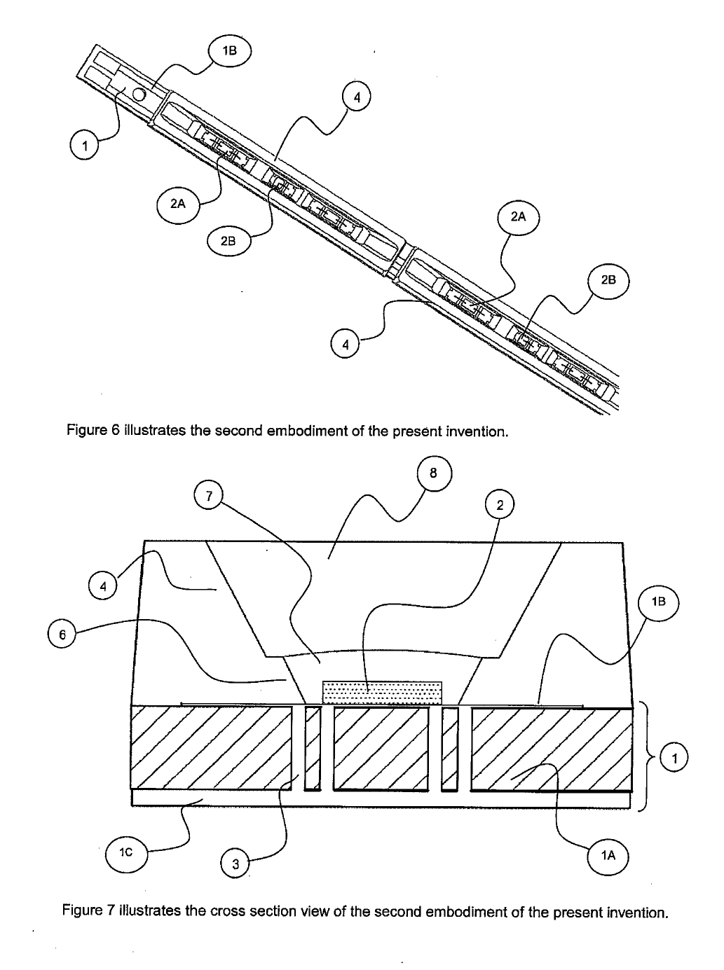

In the second embodiment of the present invention, FIGS. 6 and 7 illustrates another linear lighting module. A thermally conductive substrate (1) is used as the base of the module. The core of the substrate (1A) is an electrically non-conductive material. Suitable material include fibre glass reinforced epoxy and ceramic. On the bottom of this layer is a thermally conductive material (1C) such as copper and aluminum. Both of these layers are laminated or attached together to form the substrate (1). The electrically non-conductive material (1A) will provide the plane for electrical tracks (1B) and pads (1B) to be constructed. LED chips (2) will be attached to the pads and the electrical tracks will provide the electrical connections between the LED chips (2) and external connecting interface. The top pads where the chips are attached are connected to the bottom layer (1C) via thermally conductive holes or plug-throughs (3). These connections ensure good thermal connection between the top and bottom layers and at the same time electrical isolation between the layers. The thermal connection is provided typically via plated through holes or plugging the holes using conductive material such as copper. Multiple cavities (4) are formed on the substrate. The cavities are spaced linearly with a gap in between two adjacent cavities of less than 5 mm. These cavities are typically molded or injection molded onto the substrate. Suitable materials to form the housing included engineering plastics such as PPA, LCP and high temperature nylon. Other materials such as white silicone can also be used. In order to ensure that these cavities are strongly attached onto the thermally conductive substrate (1); half-etched holes or cut-outs (5) are made on the rear side of the substrate so that molding material can fill into these areas during molding and subsequently become an entity that will lock and grip the cavities onto the substrate. LED chips (2A, 2B) of different types and emitting different wavelength are mounted within the cavities. The combination of wavelength from the different sources will generate the desired optical property. The cavity (4) is designed in such a way whereby a secondary cavity (6) is formed within the main cavity (4). The secondary cavity (6) is first filled with clear encapsulant material or clear encapsulant material mixed with luminescence conversion elements such as phosphor (7). After the secondary cavities are filled and cured; a second clear or diffused encapsulant (8) is used to fully fill the whole cavity. This two layer configuration of encapsulation material is intended to help mix and diffuse the light from the different LED chips and ensure that we achieve a uniform light output from the light emitting surface of the module. Typical material used as encapsulant includes epoxy resin systems or silicone. Luminescence conversion elements such as phosphor are added if certain optical light conversion is required. Commonly used luminescence conversion elements include yttrium aluminum garnets (YAG), silicates and nitrides. Other materials such as silica used as diffusant may also be added in order to improve the optical characteristics of the conversion.

1. A light emitting diode (LED) module comprising
a thermally conductive substrate which is used as the base of the module;
a plurality of cavities positioned on the module and
a multiple layer configuration of encapsulation is used to fill the cavities.

2. A light emitting diode (LED) module as stated in claim 1 wherein the cavities comprise multiple secondary cavities formed within a main cavity.

3. A light emitting diode (LED) module as stated in claim 1 where the bottom thermally conductive layer of substance is thermally connected to the top pads where the light emitting chips are attached.

4. A light emitting diode (LED) module as stated in claim 1 wherein the thermally conductive substrate has half-etched holes or cut-outs on its rear side to allow molding material to fill into the half-etched holes or cut-outs so that the molding material becomes an entity that will lock and grip the cavities onto the substrate.

5. A light emitting diode (LED) module as stated in claim 1 wherein the cavities has a gap of less than 5 mm.

6. A light emitting diode (LED) module as stated in claim 2 wherein the secondary cavities are filled with clear encapsulant material or clear encapsulant material mixed with luminescence conversion elements and a second layer of clear or diffused encapsulant is then used to fully fill the whole cavity.

7. A light emitting diode (LED) module as stated in claim 1 wherein the secondary cavities hold light emitting chips of different types and emitting different wavelength.

8. A light emitting diode (LED) module as stated in claim 1 wherein the thermal connection between the top pads and the thermally conductive substrate is provided via thermally conductive hole or plug-through.
